(19) United States
(12) Patent Application Publication
(10) Pub. No.: US 2019/0037721 A1
(43) Pub. Date: Jan. 31, 2019

(54) ANODIZED ALUMINUM ALLOYS HAVING ALLOYING ELEMENTS TO ELIMINATE FILIFORM CORROSION

(71) Applicant: Apple Inc., Cupertino, CA (US)

(72) Inventors: James A. CURRAN, Morgan Hill, CA (US); William A. COUNTS, Sunnyvale, CA (US); Todd S. MINTZ, San Jose, CA (US)

(21) Appl. No.: 15/662,056

(22) Filed: Jul. 27, 2017

(51) Int. Cl. H05K 5/04; C25D 11/04; C22C 21/10

(52) U.S. Cl. CPC H05K 5/04; C22C 21/10; C25D 11/04

(57) ABSTRACT

Anodized aluminum alloys that are resistant to corrosion are described. According to some embodiments, the anodized aluminum alloys include very small amounts, even trace levels, of corrosion resistant elements with higher Gibbs free energies for oxide formation than aluminum. If the aluminum alloy includes high levels of zinc, the corrosion resistant elements can also have higher Gibbs free energies for oxide formation than zinc. The corrosion resistant elements can accumulate at an interface region of the substrate near the anodic film during the anodizing process, thereby significantly changing the alloy composition in this interface region providing surprising high resistance to certain forms of corrosion. The type and amount of corrosion resistant elements can depend on particular application requirements. In some cases, the anodized aluminum alloys are used as cosmetic appealing housing for consumer electronic products.

### CROSS-REFERENCE TO RELATED APPLICATIONS

This application is related to U.S. application Ser. No. 14/830,699, entitled “PROCESSES TO AVOID ANODIC OXIDE DELAMINATION OF ANODIZED HIGH STRENGTH ALUMINUM ALLOYS,” filed on Aug. 19, 2015; U.S. application Ser. No. 14/830,705, entitled “PROCESSES TO AVOID ANODIC OXIDE DELAMINATION OF ANODIZED HIGH STRENGTH ALUMINUM ALLOYS,” filed on Aug. 19, 2015; and U.S. application Ser. No. 14/927,225, entitled “MICRO-ALLOYING TO MITIGATE THE SLIGHT DISCOLORATION RESULTING FROM ENTRAINED METAL IN ANODIZED ALUMINUM SURFACE FINISHES,” filed on Oct. 29, 2015, each of which is incorporated herein in its entirety.

Any publications, patents, and patent applications referred to in the instant specification are herein incorporated by reference in their entireties. To the extent that the publications, patents, or patent applications incorporated by reference contradict the disclosure contained in the instant specification, the instant specification is intended to supersede and/or take precedence over any such contradictory material.

### FIELD

The described embodiments relate to anodized aluminum alloys. In particular embodiments, the anodized aluminum alloys include alloying elements that reduce corrosion, including filiform corrosion.

### BACKGROUND

Aluminum alloys are widely used materials for numerous products, due in part to their relatively high strength-to-weigh ratio. In many applications aluminum alloys are preferred over pure aluminum due to their relatively high strength. Once anodized, the aluminum alloys can be susceptible to corrosion related to the thin anodic film, especially when exposed to certain environments such as salt water and chlorinated water. Nevertheless, some consumer products that include anodized aluminum alloys may be exposed to such conditions.

### SUMMARY

This paper describes various embodiments that relate to aluminum alloy compositions that are corrosion resistant and cosmetically appealing when anodized. In particular, the aluminum alloy compositions include very small amounts of particular elements, or combination of elements, that prevent or reduce the occurrence of filiform corrosion when the anodized aluminum alloy is exposed to moisture.

According to one embodiment, an enclosure for an electronic device is described. The enclosure includes an anodized aluminum alloy substrate including an anodic film and a bulk aluminum alloy. The bulk aluminum alloy includes a corrosion resistant element at a concentration between 0.001 and 0.05 weight percent. The corrosion resistant element includes at least one of platinum, palladium, silver, gold, molybdenum, chromium, copper, titanium, vanadium, or zirconium.

According to another embodiment, a method of forming an enclosure for an electronic device is described. The method includes anodizing an aluminum alloy substrate. The aluminum alloy substrate includes a corrosion resistant element at a concentration between 0.001 and 0.05 weight percent. The corrosion resistant element includes at least one of platinum, palladium, silver, gold, molybdenum, chromium, copper, titanium, or zirconium.

According to a further embodiment, an anodized part is described. The anodized part includes an anodic film and a bulk aluminum alloy. The bulk aluminum alloy includes between about 2 and about 10 weight percent of zinc and no more than 0.05 weight percent of copper or chromium. The bulk aluminum alloy includes at least one of platinum, palladium, silver, gold, molybdenum, or copper at a concentration between 0.001 and 0.05 weight percent.

These and other embodiments will be described in detail below.

### BRIEF DESCRIPTION OF THE DRAWINGS

The disclosure will be readily understood by the following detailed description in conjunction with the accompanying drawings, wherein like reference numerals designate like structural elements.

FIG. 1 shows perspective views of devices having metal surfaces that can be manufactured using partial sealing processes described herein.

FIG. 2 shows a top view of an anodized aluminum alloy substrate with filiform corrosion.

FIG. 3 shows a cross section view of an interface region of an anodized part enriched with a corrosion resistant element.

FIG. 4 shows a graph indicating interfacial enrichment for a number of elements as a function of Gibbs free energy.

FIG. 5 shows an annotated periodic table summarizing some possible criteria for choosing a suitable corrosion resistant element.

FIGS. 6A and 6B show top views of anodized aluminum alloy substrates having corrosion resistant elements.

FIG. 7 shows a flowchart indicating a process for forming corrosion resistant anodized aluminum alloy substrates in accordance with some embodiments.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

Described herein are aluminum alloy compositions that have improved corrosion resistance when anodized. The aluminum alloy compositions include corrosion resistant elements that are generally less oxidizable compared to aluminum, and therefore can become enriched at a region near the interface between a bulk of the aluminum alloy substrate and an anodic film during the anodizing process. This enriched interface region provides a corrosion resistant barrier that protects the underlying bulk aluminum alloy from corrosion, even when the anodized substrate is exposed to corrosion inducing environments, such as exposure to salt water, sweat, chlorinated water, etc. Since the anodizing processes can concentrate the corrosion resistant elements in the interface region, the corrosion resistant elements can be added in very small concentrations, sometimes at trace levels.

The type of corrosion resistant element added to the aluminum alloy compositions can vary depending on the types and amounts of other alloying elements within the substrate, as well as other factors. For example, some aluminum alloys include relatively high concentrations of zinc to increase the strength the alloy. However, when such high strength aluminum alloys are anodized, the zinc can enrich near the interface between the between the aluminum alloy substrate and an anodic film because zinc is less readily oxidized than aluminum. In some cases, zinc has been associated with making the anodic film more prone to delamination, and thus its enrichment at the interface region should be minimized. Therefore, in some embodiments the corrosion resistant element is less readily oxidized than zinc, which can prevent or reduce the enrichment of zinc. Other factors, such as the toxicity, availability and the color of the resultant anodic film may also be taken into account when choosing the type of corrosion resistant element.

One of the advantages of the anodized aluminum alloy compositions described herein is their resistance to developing filiform corrosion, which is a type of corrosion that can occur beneath thin films. In filiform corrosion, corrosion starts at an initiation site then follows a threadlike pattern of corrosion within a substrate beneath the thin film. The enriched interface region of the anodized aluminum alloy compositions described herein can prevent the initial corrosion from occurring, and/or prevent the threadlike propagation of corrosion. Thus, the anodized alloys are well suited for consumer products that are exposed to moisture, sweat, seawater, swimming pool water, etc. For example, the anodized alloys can be used to form durable and cosmetically appealing housing for computers, portable electronic devices, wearable electronic devices, and electronic device accessories, such as those manufactured by Apple Inc., based in Cupertino, Calif.

As described herein, the terms oxide, anodic oxide, metal oxide, etc. can be used interchangeably and can refer to any suitable metal oxide materials, unless otherwise specified. Furthermore, the terms coating, layer, film, etc. can be used interchangeably and can refer to any suitable thin layer of material that, for example, covers a surface of a substrate, part, etc., unless otherwise specified. For example, an anodic oxide film can be referred to as an anodic film, anodic coating, anodic oxide coating, anodic oxide layer, metal oxide coating, oxide film, etc. Furthermore, an oxide formed by anodizing a metal substrate will generally be understood to consist of an oxide of the metal substrate. For example, an oxide formed by anodizing an aluminum or aluminum alloy substrate can form a corresponding aluminum oxide film, layer or coating.

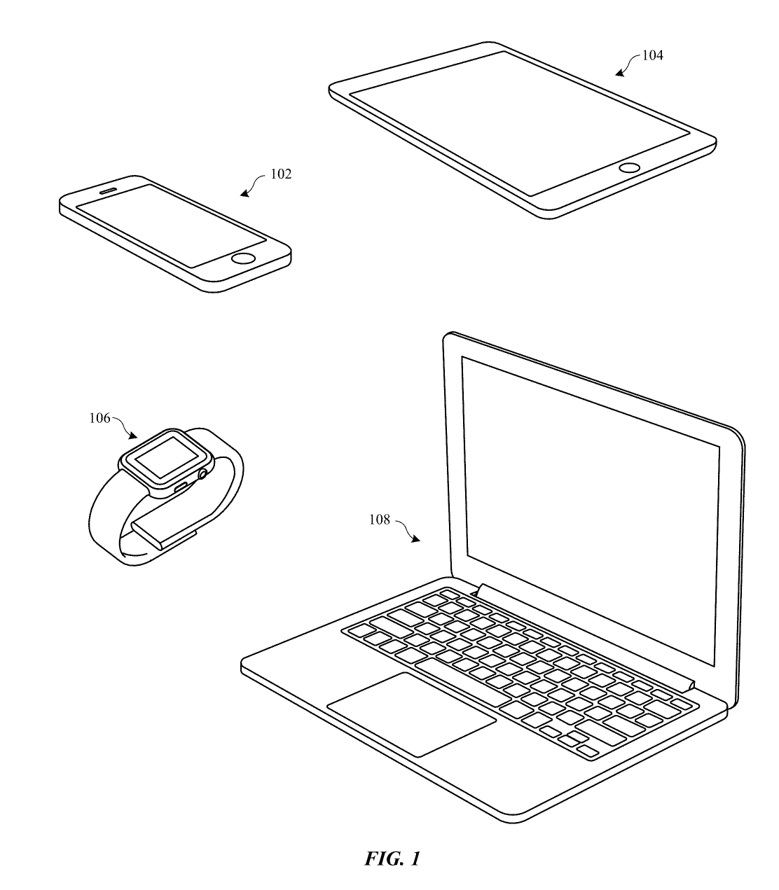

These and other embodiments are discussed below with reference to FIGS. 1-7. However, those skilled in the art will readily appreciate that the detailed description given herein with respect to these Figures is for explanatory purposes only and should not be construed as limiting.

The methods described herein can be used to form durable, corrosion resistant and cosmetically appealing metallic portions of consumer products, such as consumer electronic devices shown in FIG. 1, which includes portable phone 102, tablet computer 104, smart watch 106 and portable computer 108. Electronic devices 102, 104, 106 and 108 can each include housings that are made of metal or have metal sections. Aluminum alloys and other anodizable metals and their alloys are often used due to their ability to anodize and form a protective anodic oxide coating that protects the metal surfaces from abrasion, scratches, and other mechanical damage. Aluminum alloys may be choice metal materials due to their light weight and durability.

The metal portions of devices 102, 104, 106 and 108 can be exposed to corrosion-inducing agents, such as sweat from a user's body and hands, water from spilled liquids, seawater from the ocean or beach, and chlorinated water from swimming pools. An anodic film generally protects the underlying metal substrate from corrosion. However, if the anodic film is flawed or is damaged, such as by scratching the anodic film or subjecting the anodic film to physical impact, or thermal or mechanical stress, the corrosion-inducing agents can pass through the anodic film and reach the underlying metal substrate. Once an initial corrosion site is formed, the corrosion can propagate through the surface of the substrate by what is sometimes referred to as filiform corrosion, also referred to as underfilm corrosion.

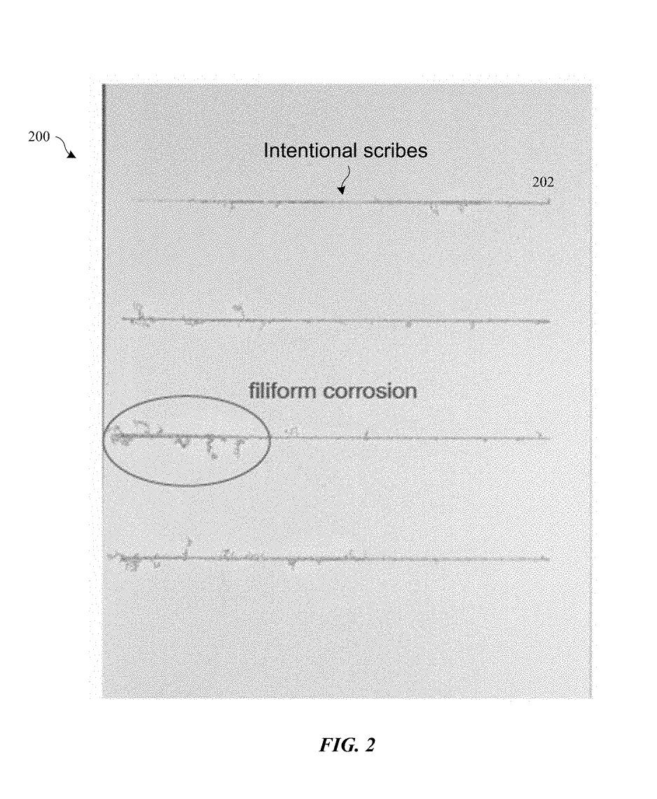

In general, filiform corrosion is a type of crevice corrosion whereby corrosion occurs in threadlike filaments underneath thin film coatings, such as lacquers, paint films, or anodic oxide films. To illustrate, FIG. 2 shows a top view of standard anodized aluminum alloy substrate 200 with intentionally formed scribe marks that locally break through the anodic film, and that appear as lines. According to one example, after scribing, the anodized aluminum alloy substrate 200 was briefly immersed in a 2 molar hydrochloric acid solution for about 30 seconds, and subsequently removed from the 2 molar hydrochloric acid solution and maintained under controlled conditions of 65° Celsius and 90% relative humidity for 5 days. The hydrochloric acidic solution passes through the anodic oxide film at the scribe marks and locally seeds an active corrosive process on the surface of the underlying aluminum alloy substrate due to a combination of the presence of chloride ions, a low pH, and water. Once the corrosion process starts, an active corrosion site in the presence of the chloride ions and water is maintained to form a corroded product. In particular, the corrosion process is maintained and fed by oxygen and water, which is wicked along a thread of the corroded product by osmotic pressure, thereby propagating in a threadlike pattern of corrosion (i.e., filiform corrosion).

The prevalence of filiform corrosion can depend, in part, on the type of aluminum alloy. For example, high strength aluminum alloys having higher concentrations of zinc (e.g., some 7000 series aluminum alloys) can be particularly sensitive to filiform corrosion. This heightened filiform corrosion sensitivity can arise, in part, because aluminum oxidizes in preference to zinc during the anodizing process due to zinc's more negative Gibbs free energy for oxide formation (less readily oxidized) compared to aluminum. As a consequence, zinc can become enriched at a region near the interface between a bulk portion of the alloy substrate and oxide layer. Such zinc enrichment is described in detail in U.S. Pat. App. Pub. Nos. US 2017-0051426A1 and US 2017-0051425A1, each of which is incorporated in its entirety herein for all purposes. The resulting film of zinc-rich region, which is immediately adjacent to the protective oxide layer, can be more susceptible to corrosion than the bulk composition of the alloy substrate. Thus, corrosion can more easily propagate along the metal/oxide interface—probably through mechanisms further exacerbated by crevice corrosion processes such as filiform corrosion.

Even if the corrosion process does not significantly attack the underlying bulk alloy, but instead remains constrained to attack of the zinc-enriched region of the alloy, it can present an obvious cosmetic defect since the metal/oxide interface is the surface that dominates the cosmetic appearance of a non-dyed or lightly dyed anodized part. Such attack, though limited in extent, can also result in adhesive failure of large areas of the protective oxide film, which can have a wider adverse effect on cosmetics. Furthermore, the resulting loss of a protective oxide film can expose the metal to further accelerated attack.

The aluminum alloys described herein include very small amounts of corrosion resistant elements that are chosen for their ability to change the composition at an interface region of the metal substrate near the anodic film and boost resistance to corrosion. The addition of the corrosion resistant elements can be especially useful in high strength, high zinc composition alloys that may be especially vulnerable to such corrosion.

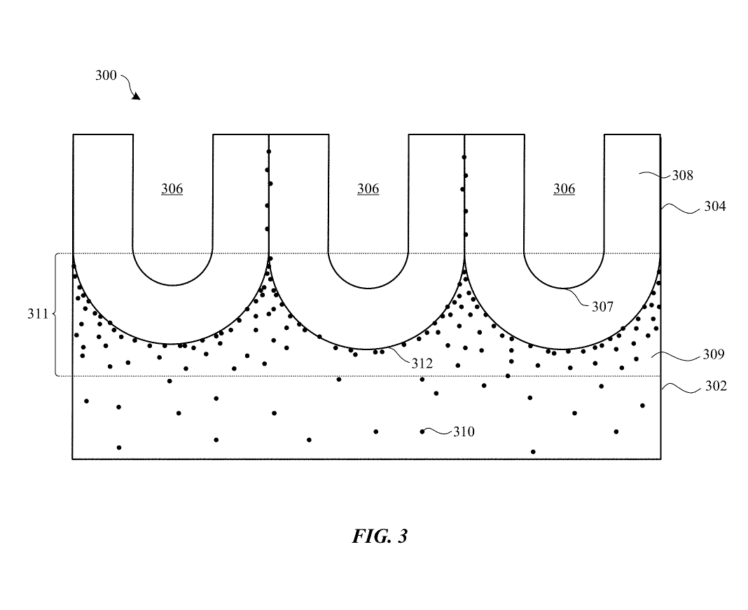

FIG. 3 shows a cross-section view of anodized part 300 having interface region 302 enriched with corrosion resistant element 310. Part 300 includes aluminum alloy substrate 302 with anodic film 304 formed from an anodizing process. In general, anodizing involves converting a surface portion of substrate 302 to a corresponding metal oxide. Thus, anodizing of aluminum alloy substrate 302 will result in anodic film 304 composed primarily of aluminum oxide (Al₂O₃). In some applications, a Type II anodizing process in accordance with Military Specification Anodizing (MIL-A-8625) standards is used, which generally involves anodizing in a sulfuric acid solution. This is because Type II anodizing can provide relatively translucent, durable, and cosmetically appealing anodic films, suitable for some consumer electronic products.

Many anodizing processes, including Type II anodizing, result in a porous anodic film 304 in that pores 306 are formed within the aluminum oxide matrix of anodic film 304. Pores 306 are defined by pore walls 308 and generally have columnar shapes that are elongated in a direction generally perpendicular to an exterior surface of anodic film 304. The size of pores 306 will vary depending, in part, on the anodizing conditions. In some applications, pores 306 will have diameters ranging between about 10 nanometers and about 30 nanometers, and pore walls 308 will have thicknesses ranging between about 5 and 20 nanometers. In some embodiments, pores 306 will have diameters that are about twice the thickness of pore walls 308. The thickness of anodic film 304 will vary depending on the application. In some applications, anodic film 304 has a thickness ranging between about 8 and 20 micrometers—in some cases between about 10 and 15 micrometers. As shown, pores 306 can have cup-like shapes at their terminuses 307 near interface 312 between substrate 302 and anodic film 304. In some cases, the region between pore terminuses 307 and interface 312 is referred to as a non-porous barrier layer region of anodic film 304.

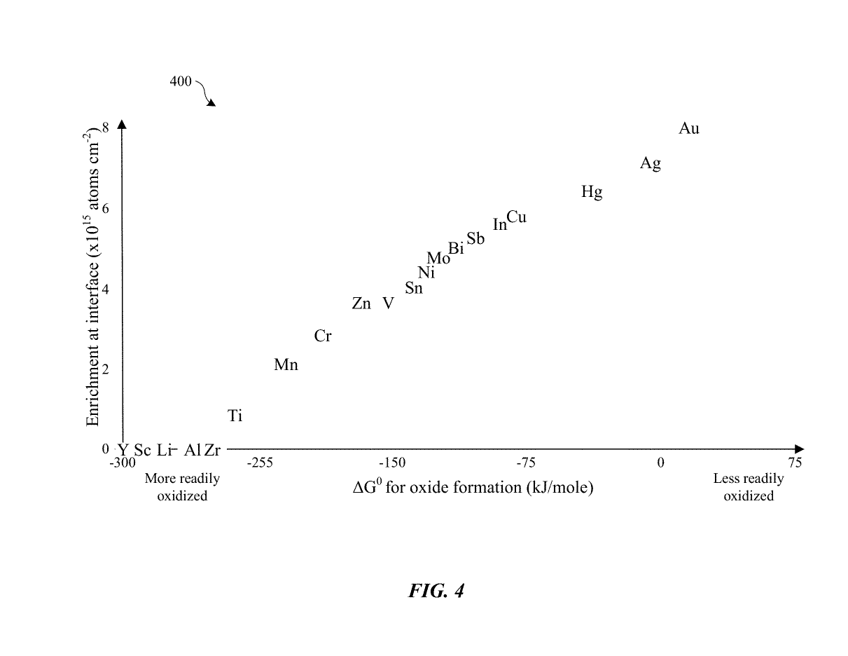

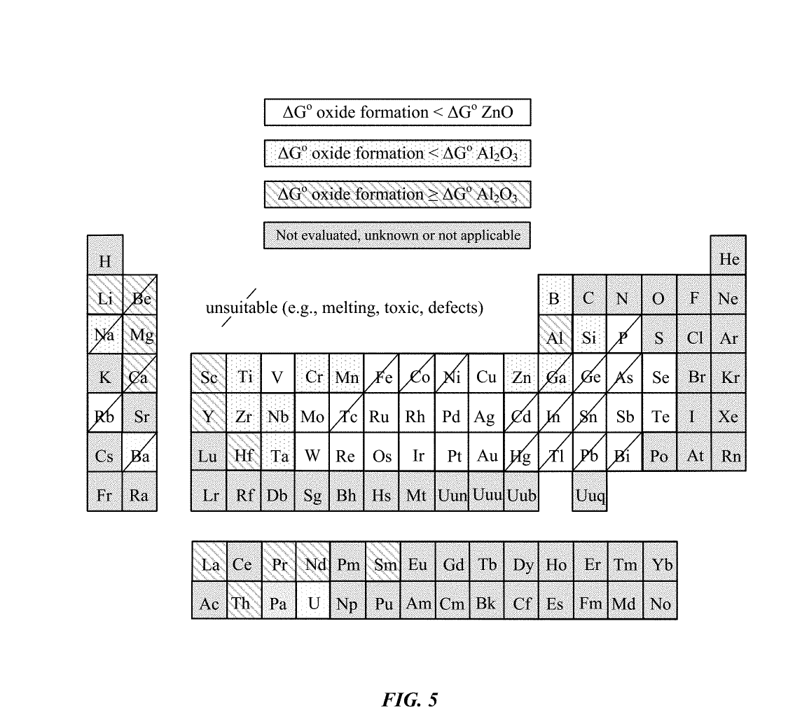

During the anodizing process, aluminum 309, which makes up the bulk of substrate 302, is converted to aluminum oxide (Al₂O₃) of anodic film 306. Any alloying elements within substrate 302 will either become oxidized and incorporated within anodic film 306, or will become enriched within region 311 (also referred to as interface region) of substrate 302 near interface 312. Whether the alloying element becomes incorporated within anodic film 306 or enriched at region 311 will depend on how readily the element oxidizes in comparison to aluminum, which can be determined by comparing the element's Gibbs free energy for oxide formation compared to that of aluminum (described in detail below with reference to FIGS. 4 and 5 and Table 1).

Elements that more readily oxidize compared to aluminum, such as magnesium, will oxidize and can become incorporated with the predominately aluminum oxide of anodic film 306. Elements that less readily oxidize compared to aluminum, such as corrosion resistant element 310, will not substantially oxidize and will instead accumulate along interface 312, thereby forming region 311 having a relatively high concentration of corrosion resistant element 310. In some embodiments, interface region 311 (also referred to as enrichment layer) is defined as the 1-2 micrometer region of substrate 302 nearest interface 312.

Since corrosion resistant element 310 is less oxidizable than aluminum, interface region 311 is less oxidizable and more corrosion resistant than bulk aluminum alloy substrate 302. Thus, if anodic film 304 become breached due to damage by heat or mechanical stress, interface region 311 will be less likely to corrode or propagate filiform corrosion. Surprisingly, even very small amounts of corrosion resistant element 310 have been found to provide this corrosion resistant benefit. This is because even small amounts of corrosion resistant element 310 within substrate 302 will become locally sufficiently enriched to a point where the concentration of corrosion resistant element 310 at interface region 311 is several atomic percent, or tens of atomic percent, higher than that of bulk aluminum alloy substrate 302 (i.e., about 1000 times higher than in the bulk alloy). Thus, corrosion resistant element 310 can be chosen with the specific intent of adjusting the composition of the thin film of interfacial metal at interface region 311. In some embodiments, aluminum alloy substrate 302 having corrosion resistant element 310 in concentrations of 0.05 weight percent (500 ppm), in some cases 0.01 weight percent (100 ppm, i.e., “trace” levels), have been found to provide an enriched interface region 211 to markedly improved corrosion resistance.

The exact level of interfacial enrichment may be difficult to determine experimentally; however, its presence has been qualitatively detected using electron energy loss spectroscopy (EELS) line scans across interface region 311 in thin Transition Electron Microscope (TEM) foil samples. Rutherford backscattering have be used to quantify interfacial enrichment in model binary alloys, showing levels of about 40 atomic percent. However, these levels may not always accurately be applied to real, thick-film oxides. In any case, it would appear that interfacial enrichment is rapidly achieved and its exact level appears to be associated with the relative magnitudes of the Gibbs free energies of oxide formation of the various alloying elements, rather than element concentrations in the bulk alloy substrate 302.

The type of corrosion resistant element 310 will depend on a number of factors, including what other alloying elements are contained within aluminum alloy 302. For example, some high strength aluminum alloys include relatively high concentrations of zinc. However, zinc can also become enriched at interface region 311 since it has a more positive Gibbs free energy for oxide formation than aluminum. As described above, such zinc enrichment has been associated with making anodic film 304 more prone to delamination, especially when the zinc combines with sulfur-containing species during a Type II anodizing, and is therefore undesirable. For example, in some cases, zinc concentrations of about 2 weight percent or greater have been found to be associated with significant delamination. In some embodiments, zinc concentrations of about 4 weight percent or greater have been associated with significant delamination. Hence, for those aluminum alloys having such higher levels of zinc, it can be beneficial for corrosion resistant element 310 to have a more positive Gibbs free energy for oxide formation than zinc. This way, corrosion resistant element 310 can become enriched at interface region 311 in preference over zinc, and in doing so displace zinc at interface region 311.

Note that some zinc-rich alloys include non-commercially available high strength alloys, such as those described in U.S. Pat. App. Pub. Nos. US 2017-0051426A1 and US 2017-0051425A1. For example, in some embodiments, the aluminum alloys described herein include stoichiometric amounts of zinc and magnesium to form MgZn₂ η′ precipitates (e.g., atomic percent zinc equals 2 times atomic percent magnesium). That is, in some embodiment the atomic percent ratio of magnesium to zinc is about 1:2. In some cases, these Al—Zn—Mg alloys include about 5.5 weight percent zinc and about 1 weight percent magnesium. For example, the aluminum alloys can include 5.45, 5.61, 5.49, or 5.69 weight percent zinc and 0.7, 1.1 0.9, 1.9, 1.5, or 0.05 weight percent magnesium.

The Gibbs free energy for oxide formation can thus be one of the key properties that govern the level to which corrosion resistant element 310 will enrich at interface 311 during anodizing. FIG. 4 shows graph 400 comparing levels of interfacial enrichment as a function of Gibbs free energy (ΔG°) for a number of elements. Graph 400 is a modified version of data provided in Corrosion Science, Vol. 39, No. 4, pp. 731-737 (1997). The x-axis indicates Gibbs free energy (ΔG°) for oxide formation of each element, and the y-axis indicates an amount of enrichment of each element at the interface between an anodic film and bulk aluminum alloy substrate, expressed in atoms (×10¹⁵) per cm².

As described above, elements having more positive ΔG° for oxide formation than zinc is a good first approximation for determining types of corrosion resistant elements that can accumulate at the anodic oxide-substrate interface in preference over zinc. Graph 400 indicates that vanadium (V), tin (Sn), nickel (Ni), molybdenum (Mo), bismuth (Bi), antimony (Sb), indium (In), copper (Cu), mercury (Hg), silver (Hg), and gold (Au) have higher ΔG° for oxide formation compared to zinc (Zn). Therefore, these elements are expected to enrich at the interface region in preference to zinc, and may be good candidates as corrosion resistant elements for aluminum alloys with relatively high concentrations of zinc (e.g., 2 weight percent or greater, or 4 weight percent or greater), such as some 7000 series aluminum alloys.

For aluminum alloys that have lower levels of zinc, such as some 6000 and 2000 series aluminum alloys, zinc enrichment may not be a significant issue. Thus, the range of possible corrosion resistant elements can be expanded to include those having more negative ΔG° than zinc and more positive ΔG° than aluminum. According to graph 400, this expands the range of elements to include zirconium (Zr) titanium (Ti), manganese (Mn), chromium (Cr), zinc (Zn), vanadium (V), tin (Sn), nickel (Ni), molybdenum (Mo), bismuth (Bi), antimony (Sb), indium (In), copper (Cu), mercury (Hg), silver (Hg), and gold (Au) have higher ΔG° for oxide formation than aluminum (Al). These elements, therefore, may be good candidates as corrosion resistant elements for aluminum alloys having lower concentrations of zinc (e.g., lower than 2 weight percent, or lower than 4 weight percent).

Table 1 below lists calculated oxide formation energies (ΔG°) of a number of elements based on particular oxidation states and solubility based on face centered cubic (fcc) crystal structure.

TABLE 1
Oxide formation energies

| | | −ΔG | |
|---|---|---|---|
| Elements | Oxides | (kCal/mole O2) | Solubility in fcc (Al) |
| Ag | Ag₂O | 14 | 1 at. %, 300 C. |
| Pt | Pt₃O₄ | 22 | <<0.1 at %, 300 C. |
| Rh | Rh₂O₃ | 42 | |
| Ir | IrO₃ | 43 | |
| Se | SeO₂ | 54 | |
| Os | OsO₂ | 62 | |
| Tl | Tl₂O | 69 | |
| Te | TeO₂ | 77 | |
| Cu | Cu₂O | 80 | 0.2 at. %, 300 C. |
| Bi | Bi₃O₄ | 104 | |
| Sb | Sb₂O₃ | 111 | |
| Ni | NiO | 114 | <0.01 at. %, 300 C. |
| Co | CoO | 115 | <0.01 at. %, 500 C. |
| Mo | MoO₂, MoO₃ | 127, 106 | |
| Ge | GeO₂ | 129 | 0.6 at. %, 300 C. |
| Fe | Fe₃O₄ | 130 | |
| W | WO₃ | 133 | 0.01 at. %, 500 C. |
| Sn | SnO₂ | 139 | |
| V | V₂O₅ | 140 | 0.1 at. %, 500 C. |
| In | In₂O₃ | 157 | |
| Rb | Rb2O | 158 | |
| Zn | ZnO | 166 | |
| Nb | NbO₂, NbO | 176, 187 | |
| Cr | Cr₂O₃ | 179 | |
| Mn | MnO | 184 | 0.12 at. %, 500 C. |
| Ta | Ti₂O₅ | 198 | |
| Si | SiO₂ | 217 | |
| Ti | Ti₂O₃ | 242 | 0.26 at. %, 500 C. |
| Er | Er₂O₃ | 260 | |
| Zr | ZrO₂ | 262 | 0.02 at. %, 500 C. |
| Hf | HfO₂ | 265 | 0.04 at. %, 500 C. |
| Al | Al₂O₃ | 277 | |
| Sr | SrO | 280 | |
| Ce | Ce₂O₃ | 285 | |
| Li | LiO₂ | 285 | |
| La | La₂O₃ | 285 | 0.001 at. %, 500 C. |
| Mg | MgO | 286 | |
| Gd | Gd₂O₃ | 287 | |
| Eu | EuO | 290 | |
| Sc | Sc₂O₃ | 310 | 0.04 at. %, 500 C. |
| Ca | CaO | 320 | |
| Y | Y₂O₃ | 320 | 0.008 at. %, 500 C. |

According to Table 1, elements that can be expected to enrich at the interface region of an anodized aluminum alloy having high concentrations of zinc include (in approximate order of their relative Gibbs free energy for oxide formation): Ag, Pt, Rh, Ir, Se, Os, Ti, Te, Cu, Bi, Sb, Ni, Co, Mo, Ge, Fe, W, Sn, V, In, and Rb. Elements, which might enrich in aluminum alloys where zinc is not a primary alloying element also include: Zn, Nb, Cr, Mn, Ta, Si, Ti, Er, Zr, and Hf. Examples of elements which will not enrich at the interface of any aluminum alloy include S, Ce, Li, La, Mg, Gd, Eu, Sc, Ca, and Y.

FIG. 5 shows an annotated periodic table summarizing some criteria for choosing suitable corrosion resistant elements, in accordance with some embodiments. Elements are categorized based on their ΔG° for oxide formation less than that of ZnO formation, less than that of Al₂O₃ formation, and greater than or equal to that of Al₂O₃ formation.

FIG. 5 indicates that elements having ΔG° for oxide formation less than that of ZnO formation, and would therefore be likely to enrich in preference over zinc at an interface region, include Rb, V, Mo, W, Tc, Re, Fe, Ru, Os, Co, Rh, Ir, Ni, Pd, Pt, Cu, Ag, Au, Cd, Hg, In, Tl, Ge, Sn, Pb, P, As, Sb, Bi, Se, and Te. Of the elements that can be expected to enrich at the interface region, some can be excluded from consideration due to low melting point that might inhibit certain metallurgical operations. (e.g., Hg, and possibly also In, Sn, Cd, Pb, Bi, Ge), although the very low levels required make this limitation somewhat less strict. The solubility of the element in aluminum may eliminate further candidates, although the very low levels of alloying required for this effect to occur again make this consideration less critical. Other elements can be ruled out because of hazards such as radioactivity, toxicity or high reactivity (e.g., U, Tc, Pb, Cd, Be, As, Rb). A further consideration can include cost, or supply constraints, which could eliminate elements such as Os, Ir, Pt, Rh, and also elements such as Co, but it should be noted that at trace levels, elements such as Ag, although expensive, remain viable. Thus, in some embodiments where the aluminum alloy substrate includes at least 2 weight percent of zinc (in some cases at least 4 weight percent of zinc), the corrosion resistant element can include at least one of Pt (platinum), Pd (palladium), Ag (silver), Au (gold), Mo (molybdenum), V (vanadium), or Cu (copper).

For those aluminum alloys that include lower concentrations of zinc, and which there is little or no interfacial enrichment of zinc-sulfur delamination-promoting species, it can be less important to use elements having ΔG° less readily oxidizable than zinc. Examples of such aluminum alloys with lower zinc concentrations can include 6000 or 2000 series aluminum alloys. Thus, elements having ΔG° for oxide formation less than that of aluminum, in addition to elements having ΔG° less readily oxidizable than zinc, can be included for these types of aluminum alloy substrates. According to the chart of FIG. 5, this further includes Na, Ba, Ti, Zr, Nb, Ta, Cr, Mn, Zn, B, Ga, Si, and Ur. However, Na, Ba, and Ga may be unsuitable due to toxicity, melting points, and/or propensity for causing visible defects within an anodic film once the aluminum alloy substrate is anodized. Thus, in some embodiments where the aluminum alloy substrate includes less than 2 weight percent of zinc (in some cases lower than 4 weight percent of zinc), the corrosion resistant element can include at least one of Pt (platinum), Pd (palladium), Ag (silver), Au (gold), Mo (molybdenum), Cr (chromium), Cu (copper), Ti (titanium), V (vanadium), or Zr (zirconium).

Another critically important criterion for choosing an appropriate corrosion resistant element is the element's electrode potential. In order for the end product to resist corrosion better than the bulk alloy, the local composition of the interface region should have higher electrode potentials than aluminum (or the aluminum-zinc film formed in an anodized Al—Zn—Mg alloy). Table 3 below lists calculated standard electrode potentials for half reactions for the reduction of different metal ions (for 1 molar aqueous solutions of metal ions at atmospheric pressure and 25 degrees C.

TABLE 2
Standard electrode potential
Standard electrode potentials
(25 C., 1 atmosphere, 1 mol/L solution)

| Reduction half reaction | E° (V) |
|---|---|
| Au³⁺ +3e− -> Au(s) | 1.52 |
| Pt²⁺ +2e− -> Pt(s) | 1.19 |
| Pd²⁺ +2e− -> Pd(s) | 0.92 |
| Hg²⁺ +2e− -> Hg(l) | 0.85 |
| Ag⁺ +e− -> Ag(s) | 0.80 |
| Cu⁺ +e− -> Cu(s) | 0.52 |
| Cu²⁺ +2e− -> Cu(s) | 0.34 |
| Bi³⁺ +3e− -> Bi(s) | 0.31 |
| Re³⁺ +3e− -> Re(s) | 0.30 |
| Ge⁴⁺ +4e− -> Ge(s) | 0.12 |
| Fe³⁺ +3e− -> Fe(s) | −0.04 |
| Pb²⁺ +2e− -> Pb(s) | −0.13 |
| Sn²⁺ +2e− -> Sn(s) | −0.14 |
| Mo³⁺ +3e− -> Mo(s) | −0.20 |
| Ni²⁺ +2e− -> Ni(s) | −0.25 |
| Co²⁺ +2e− -> Co(s) | −0.28 |
| In³⁺ +3e− -> In(s) | −0.34 |
| Tl⁺ +e− -> Tl(s) | −0.34 |
| Cd²⁺ +2e− -> Cd(s) | −0.40 |
| Fe²⁺ +2e− -> Fe(s) | −0.44 |
| Ga³⁺ +3e− -> Ga(s) | −0.53 |
| Cr³⁺ +3e− -> Cr(s) | −0.74 |
| Zn²⁺ +2e− -> Zn(s) | −0.76 |
| Nb³⁺ +3e− -> Nb(s) | −1.10 |
| V²⁺ +2e− -> V(s) | −1.13 |
| Mn²⁺ +2e− -> Mn(s) | −1.18 |
| Ti³⁺ +3e− -> Ti(s) | −1.37 |
| Zr⁴⁺ +4e− -> Zr(s) | −1.45 |
| Al³⁺ +3e− -> Al(s) | −1.66 |
| Be²⁺ +2e− -> Be(s) | −1.70 |
| Sc³⁺ +3e− -> Sc(s) | −2.08 |
| Mg²⁺ +2e− -> Mg(s) | −2.36 |
| Na⁺ +e− -> Na(s) | −2.71 |
| Ca²⁺ +2e− -> Ca(s) | −2.87 |
| Sr²⁺ +2e− -> Sr(s) | −2.89 |
| Ba²⁺ +2e− -> Ba(s) | −2.90 |
| Cs⁺ +e− -> Cs(s) | −2.92 |
| K⁺ +e− -> K(s) | −2.92 |
| Rb⁺ +e− -> Rb(s) | −2.92 |
| Li⁺ +e− -> Li(s) | −3.04 |

Table 2 indicates which metal ions are calculated to be less or more likely to oxidize (corrode) compared to aluminum (Al³⁺). It should be noted that the calculated E*(V) values in Table 2 are for half reactions of only some oxidation states of some metal ions, and therefore does not take into account other possible oxidation states of metal ions. This second criterion (high standard electrode potential for metal ion reduction) favors (in approximate order of resulting surface corrosion resistance): Au, Pt, Pd, Ag, Cu, Bi, Re, Ge, Sn Mo, Ni, Co, In, Fe, Ga, Cr, Zn, V, Mn, Ti, and Zr.

Table 3 below list a galvanic series of some metals and metal compounds, listed in increasing order of likelihood of corroding (i.e., most likely to give up electrons) when exposed to seawater (from Materials and Process Selection for Engineering Design, 2^{nd} edition (2008) by Mahmoud M. Farag, Table 3.1).

TABLE 3
Galvanic Series

Mercury
Platinum
Gold
Zirconium Graphite
Titanium
Hastelloy C Monel
Stainless Steel (316-passive)
Stainless Steel (304-passive)
Stainless Steel (400-passive)
Nickel (passive oxide)
Silver
Hastelloy 62Ni, 17Cr
Silver solder
Inconel 6 1Ni, 17Cr
Aluminum (passive Al₂0₃)
70/30 copper-nickel
90/10 copper-nickel
Bronze (copper/tin)
Copper
Brass (copper/zinc)
Alum Bronze Admiralty Brass
Nickel
Naval Brass Tin
Lead-tin
Lead
Hastelloy A
Stainless Steel (active)
316 404 430 410
Lead Tin Solder
Cast iron
Low-carbon steel (mild steel)
Manganese Uranium
Aluminum Alloys
Cadmium
Aluminum Zinc
Beryllium
Magnesium

The data of Table 3 takes into consideration multiple possible oxidation states of metal ions, and thus may be more realistic estimations as to elements' corrosion resistances in some cases. Table 3 indicates that those metals and metal compounds above aluminum alloys will act as a cathode and will not substantially corrode compared to aluminum alloys, while those metals and metal compounds below aluminum alloys will act as an anode and will preferentially corrode compared to aluminum alloys. In some consumer electronic products, such as enclosures that are handled by users, preferred metals listed on Table 3 can include platinum, gold, titanium, silver, and/or copper. While, in some examples, zinc may itself be more detrimental than helpful to resisting corrosion. As described above, however, the presence and amount of other alloying elements such as zinc may also dictate which metals may be preferred.

Of the candidate elements that satisfy all of the above conditions, some may be unfavorable to detrimental effects on oxide adhesion, such as zinc and tin. Several others may result in yellow discoloration of an otherwise substantially clear and colorless anodic oxide film, and may therefore be undesirable for cosmetic reasons, which may be of high importance in consumer products. These may include gold, silver, chromium, and copper. Levels of these elements may have to be tightly controlled to avoid easily perceived discoloration or color variation since levels of as little as 500 ppm may, in some cases, cause increases in yellowness (i.e., b* values greater than 1 as measured using CIE L*a*b* 1976 color space standards). Thus, in some cases that aluminum alloy includes no more than about 0.05 weight percent of yellowing elements (e.g., iron, copper, gold, silver and/or chromium)—in some cases, no more than about 0.01 weight percent (trace levels). In some cases, the aluminum alloy includes no more than a prescribed amount of other alloying elements, such as silicon (e.g., no more than 0.05 or 0.01 weight percent). Platinum, palladium, molybdenum, and zirconium generally do not impart yellow discoloration on the resultant anodic oxide and may therefore be preferred candidates in some applications where color clarity is important, depending on the concentration of the alloying element and amount of discoloration. Of these, molybdenum and zirconium may be preferred in some embodiments due to their relatively low cost.

The concentration of the corrosion resistant elements will be set by numerous factors including solubility in aluminum and any adverse impact on grain structure. For example, zirconium at about 500 ppm may inhibit formation of an equiaxed grain structure and instead lead to obvious directionality and apparent “streaking” in cosmetic surfaces. Thus, a level of 500 ppm or less of zirconium might be set as a maximum. This 500 ppm maximum may also allow recycling of the aluminum alloy without exceeding levels for many commercial alloy specifications that commonly alloy for up to 0.05 weight percent of “other” unspecified alloying elements.

It should be noted that more than one type of corrosion resistant element may be used. For example, an aluminum alloy can include a combination of molybdenum and platinum, or a combination of molybdenum, platinum and copper, etc. In some embodiments, the total weight percent of the combination of corrosion resistant elements is between about 0.001 and about 0.05 weight percent—in some cases, between about 0.01 and about 0.05 weight percent. Furthermore, it should be noted that the corrosion resistant element(s) are not necessarily limited to those listed above, and that any suitable element(s) may be used. Moreover, the corrosion resistant element may be added to other corrosion-prone alloys, such as aluminum-lithium based alloys, where the limiting element (as pertains to preferential enrichment at the interface according to the relative Gibbs free energy for oxide formation) would be aluminum or any suitable ternary precipitate former such as zinc.

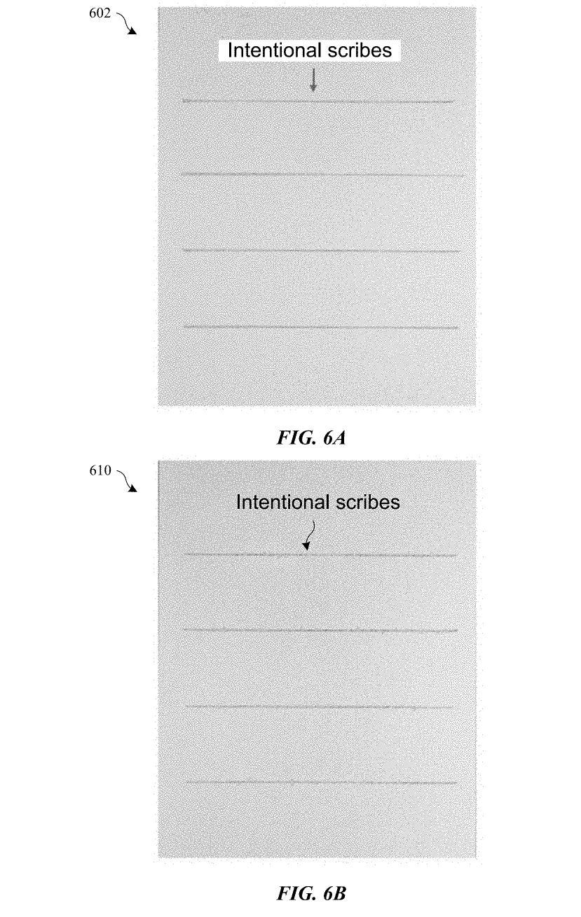

FIGS. 6A and 6B show a top views of anodized aluminum alloy substrates 600 and 610, respectively, which have corrosion resistant elements. Anodized aluminum substrate 600 includes 5.5 weight percent of zinc, 1 weight percent of magnesium, and about 0.01 weight percent of molybdenum as a corrosion resistant element, and aluminum as the remainder of the metal substrate. Anodized aluminum substrate 610 includes 5.5 weight percent of zinc, 1 weight percent of magnesium, and 0.01 weight percent of silver a corrosion resistant element, and aluminum as the remainder of the metal substrate. In both substrates 600 and 610, zinc and magnesium are added as alloying elements to increase the strength of metal substrate.

In some examples, substrates 600 and 610 were each intentionally scribed with marks that locally break through the anodic film in a process similar to the process described in conjunction with FIG. 2A. After scribing, both substrates 600 and 610 were exposed to a 2 molar hydrochloric acid solution for about 30 seconds, and subsequently removed from the 2 molar hydrochloric acid solution and maintained under controlled conditions of 65° Celsius and 90% relative humidity for 5 days. As illustrated in FIGS. 6A-6B, the substrates 600 and 610 exhibited very little evidence of corrosion and substantially no visible filiform corrosion. Similar corrosion resistant results were also found with samples having 0.01 weight percent copper.

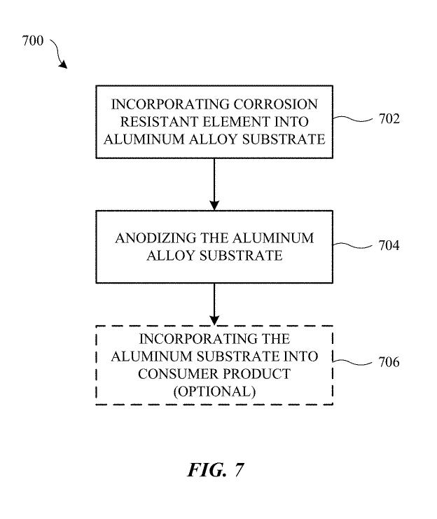

FIG. 7 shows flowchart 700 indicating a process for forming a corrosion resistant aluminum alloy substrate suitable for consumer products, such as housings or enclosures for consumer electronic devices. At 702, a corrosion resistant element is added to aluminum or an aluminum alloy. In some embodiments, the corrosion resistant element includes at least one of Pt (platinum), Pd (palladium), Ag (silver), Au (gold), Mo (molybdenum), Cr (chromium), Cu (copper), Ti (titanium), V (vanadium), and Zr (zirconium). In some embodiment, the aluminum alloy is a high strength alloy and also includes relatively high levels of zinc, such as about 2.0 weight percent (e.g., 1.5, 1.9, 2.2, or 2.9 weight percent) or higher. For example, the aluminum alloy can include between about 2.0 and 10 weight percent of zinc. In these cases, it may be beneficial for the corrosion resistant element to having more positive ΔG° for oxide formation (less readily oxidizable) than zinc. Examples of suitable corrosion resistant elements for such high strength alloys can include at least one of Pt (platinum), Pd (palladium), Ag (silver), Au (gold), Mo (molybdenum), or Cu (copper). The corrosion resistant element can be added in very small amounts, in some cases, in trace amounts. In some embodiments, the corrosion resistant element is added at a concentration between about 0.001 and about 0.05 weight percent.

At 704, the aluminum alloy substrate is anodized in order to convert surface portions of the substrate to an aluminum oxide coating. During the anodizing process, the corrosion resistant element(s) enrich at an interface region of the substrate between the aluminum oxide coating the underlying bulk aluminum alloy. The concentration of the corrosion resistant element is highly concentrated at the interface region, sometimes making up as much as 40 atomic percent or higher. Any suitable anodizing process can be used. In some embodiment, a Type II anodizing process, which involves using a sulfuric acid based anodizing bath, is used. The final thickness of the aluminum oxide coating can vary depending on application requirements. In some applications, the aluminum oxide coating has a thickness ranging between about 8 and 20 micrometers (e.g., 8.1, 8.5, 12.0, 20.5, or 20.9 micrometers)—in some cases between about 10 and 15 micrometers (e.g., 9.1, 9.5, 12.5, 15.5, or 15.9 micrometers).

At 706, the aluminum alloy substrate is optionally incorporated into a consumer product. In some embodiments, the consumer product is an electronic device and the aluminum alloy substrate corresponds to an enclosure or housing for the electronic device that is visible and touchable to a consumer. In some applications, the aluminum oxide coating should be relatively transparent and colorless—for example, characterized as having a b* value no more than 1. Since the underlying substrate includes an interface region enriched with the corrosion resistant element, the substrate has greater resistance to corrosion (e.g., filiform corrosion) even if the integrity of the aluminum oxide coating breached from damage cause by, for example, scratches, dents, and heat stress. Furthermore, the substrate is less likely to experience corrosion even if exposed to corrosive environments, such as moisture, seawater, sweat, chlorinated water, etc.

The foregoing description, for purposes of explanation, uses specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. An enclosure for an electronic device, the enclosure comprising:
an anodized aluminum alloy substrate including an anodic film and a bulk aluminum alloy, wherein the bulk aluminum alloy includes a corrosion resistant element at a concentration between 0.001 and 0.05 weight percent, the corrosion resistant element including at least one of platinum, palladium, silver, gold, molybdenum, chromium, copper, titanium, vanadium, or zirconium.

2. The enclosure of claim 1, wherein the bulk aluminum alloy includes at least 2 weight percent of zinc, and wherein the corrosion resistant element includes at least one of platinum, palladium, silver, gold, molybdenum, chromium, vanadium, or copper.

3. The enclosure of claim 2, wherein the bulk aluminum alloy includes about 5.5 weight percent of zinc and about 1.0 weight percent of magnesium.

4. The enclosure of claim 1, wherein the corrosion resistant element includes at least one of molybdenum, copper, or zirconium.

5. The enclosure of claim 1, wherein the bulk aluminum alloy includes magnesium and zinc, and the atomic percent ratio of magnesium to zinc is about 1:2.

6. The enclosure of claim 1, wherein the bulk aluminum alloy includes between about 2 and about 10 weight percent of zinc

7. The enclosure of claim 1, wherein the bulk aluminum alloy includes no more than 0.05 weight percent of copper.

8. The enclosure of claim 1, wherein the bulk aluminum alloy includes no more than 0.05 weight percent of chromium.

9. The enclosure of claim 1, wherein the bulk aluminum alloy includes less than 2 weight percent of zinc.

10. The enclosure of claim 1,wherein the corrosion resistant element is enriched at a region of the anodized aluminum alloy substrate near an interface between the anodic film and the bulk aluminum alloy.

11. The enclosure of claim 10, wherein the anodic film has a thickness between about 10 and 15 micrometers.

12. The enclosure of claim 10, wherein the anodic film is characterized as having a b* value no greater than 1.

13. A method of forming an enclosure for an electronic device, the method comprising:
anodizing an aluminum alloy substrate, wherein the aluminum alloy substrate includes a corrosion resistant element at a concentration between 0.001 and 0.05 weight percent, the corrosion resistant element including at least one of platinum, palladium, silver, gold, molybdenum, chromium, copper, titanium, or zirconium.

14. The method of claim 13, wherein the anodizing forms an anodic film characterized as having a b* value no greater than 1.

15. The method of claim 13, wherein the anodizing forms an anodic film having a thickness between about 10 and 15 micrometers.

16. The method of claim 13, wherein the bulk aluminum alloy includes no more than 0.01 weight percent of copper, and no more than 0.01 weight percent of chromium.

17. An anodized part, comprising:
an anodic film and a bulk aluminum alloy, wherein the bulk aluminum alloy includes between about 2.0 and about 10 weight percent of zinc and no more than 0.05 weight percent of copper or chromium,
wherein the bulk aluminum alloy includes at least one of platinum, palladium, silver, gold, molybdenum, or copper at a concentration between 0.001 and 0.05 weight percent.

18. The anodized part of claim 17, wherein the bulk aluminum alloy includes magnesium and zinc at an atomic percent ratio about 1:2.

19. The anodized part of claim 17, wherein the anodic film is characterized as having a b* value no greater than 1.

20. The anodized part of claim 17, wherein the bulk aluminum alloy includes no more than 0.01 weight percent of copper or chromium.
